(19) United States
(12) Patent Application Publication
(10) Pub. No.: US 2024/0372510 A1
(43) Pub. Date: Nov. 7, 2024

(54) RADIO FREQUENCY MODULE AND COMMUNICATION APPARATUS

(71) Applicant: Murata Manufacturing Co., Ltd., Kyoto (JP)

(72) Inventor: Atsushi HORITA, Nagaokakyo-shi, Kyoto (JP)

(73) Assignee: Murata Manufacturing Co., Ltd., Kyoto (JP)

(21) Appl. No.: 18/736,619

(22) Filed: Jun. 7, 2024

Related U.S. Application Data
(63) Continuation of application No. PCT/JP2022/044286, filed on Nov. 30, 2022.

(30) Foreign Application Priority Data
Dec. 28, 2021 (JP) 2021-214798

(51) Int. Cl. H03F 1/32; H03F 3/24

(52) U.S. Cl. CPC H03F 1/32; H03F 3/245; H03F 2200/372; H03F 2200/451

(57) ABSTRACT

A radio frequency module capable of suppressing a situation where a power supply wiring unit electromagnetically interferes with an amplifier inside a semiconductor integrated circuit. The radio frequency module includes a mounting substrate, a semiconductor integrated circuit, and a power supply wiring unit. The semiconductor integrated circuit is arranged at the mounting substrate. The semiconductor integrated circuit includes a first amplifier, a second amplifier, and a power supply electrode. The first amplifier includes a first power supply terminal. The second amplifier includes a second power supply terminal. A power supply voltage from the mounting substrate is input to the power supply electrode. The power supply wiring unit connects the power supply electrode to the first power supply terminal and the second power supply terminal.

### CROSS-REFERENCE TO RELATED APPLICATIONS

This is a continuation application of PCT/JP2022/044286 filed on Nov. 30, 2022, designating the United States of America, which is based on and claims priority to Japanese Patent Application No. JP 2021-214798 filed on Dec. 28, 2021. The entire contents of the above-identified applications, including the specifications, drawings and claims, are incorporated herein by reference in their entirety.

### TECHNICAL FIELD

The present disclosure relates to a radio frequency module and a communication apparatus.

### BACKGROUND ART

A radio frequency module described in Patent Document 1 includes a module substrate (mounting substrate) and a semiconductor integrated circuit. The semiconductor integrated circuit is mounted on a main surface of the module substrate. The semiconductor integrated circuit includes two reception low noise amplifiers (first amplifier and second amplifier).

In the radio frequency module described in Patent Document 1, the semiconductor integrated circuit includes a power supply electrode and a power supply wiring unit. The power supply electrode is an electrode to which a power supply voltage from the mounting substrate is input. The power supply wiring unit is arranged inside the semiconductor integrated circuit and connects the power supply electrode to power supply terminals of the two reception low noise amplifiers.

### CITATION LIST

### Patent Document

Patent Document 1: Japanese Unexamined Patent Application Publication No. 2021-48565

### SUMMARY OF DISCLOSURE

### Technical Problem

In recent years, as radio frequency modules have decreased in size and have included more mounting components, the space inside the semiconductor integrated circuit where the power supply wiring unit can be arranged has been reduced. Thus, it has been difficult to secure the space between the power supply wiring unit and the amplifiers, and there has been such a problem that the amplifiers are susceptible to electromagnetic interference from the power supply wiring unit.

In view of the problem mentioned above, it is an object of the present disclosure to provide a radio frequency module and a reception apparatus capable of suppressing a situation where a power supply wiring unit electromagnetically interferes with an amplifier inside a semiconductor integrated circuit.

### Solution to Problem

A radio frequency module according to an aspect of the present disclosure includes a mounting substrate, a semiconductor integrated circuit, and a power supply wiring unit. The semiconductor integrated circuit is arranged at the mounting substrate. The semiconductor integrated circuit includes a first amplifier, a second amplifier, and a power supply electrode. The first amplifier includes a first power supply terminal. The second amplifier includes a second power supply terminal. A power supply voltage from the mounting substrate is input to the power supply electrode. The power supply wiring unit connects the power supply electrode to the first power supply terminal and the second power supply terminal. The power supply wiring unit includes a terminal-to-terminal wiring part that connects the first power supply terminal to the second power supply terminal. The terminal-to-terminal wiring part includes a substrate-side wiring part that is arranged at the mounting substrate.

A communication apparatus according to an aspect of the present disclosure includes the radio frequency module and a signal processing circuit. The signal processing circuit is connected to the radio frequency module and performs signal processing for a radio frequency signal.

### Advantageous Effects of Disclosure

The radio frequency module and the communication apparatus according to the aspects of the present disclosure described above have an advantage of being capable of suppressing a situation where the power supply wiring unit electromagnetically interferes with the amplifier in the semiconductor integrated circuit.

### BRIEF DESCRIPTION OF DRAWINGS

FIG. 1 is a configuration diagram illustrating an example of a communication apparatus according to an embodiment.

FIG. 2 is a plan view of a first main surface of a mounting substrate of a radio frequency module provided in the communication apparatus.

FIG. 3 is a plan view of a second main surface of the mounting substrate of the radio frequency module assuming seen through from the first main surface side.

FIG. 4 is a cross-section view taken along line X1-X1 of FIG. 2 and along line X2-X2 of FIG. 3.

FIG. 5 is a cross-section view of a radio frequency module according to a first modification.

FIG. 6A is a plan view of a semiconductor integrated circuit according to a second modification assuming seen from the first main surface side of the mounting substrate of the radio frequency module, and FIG. 6B is a circuit diagram of a low noise amplifier included in the semiconductor integrated circuit.

FIG. 7A is a plan view of a semiconductor integrated circuit according to a third modification assuming seen from the first main surface side of the radio frequency module, and FIG. 7B is a circuit diagram of a low noise amplifier included in the semiconductor integrated circuit.

FIG. 8 is a plan view of a semiconductor integrated circuit according to a fourth modification assuming seen from the first main surface side of the radio frequency module.

### DESCRIPTION OF EMBODIMENTS

Hereinafter, a radio frequency module and a communication apparatus according to an embodiment will be described with reference to drawings. Regarding component elements described herein and illustrated in the drawings, sizes, thicknesses, and dimensional relationships described herein and illustrated in the drawings are examples, and these component elements are not limited to the examples described herein and illustrated in the drawings.

### EMBODIMENT

### (1) Overview of Radio Frequency Module

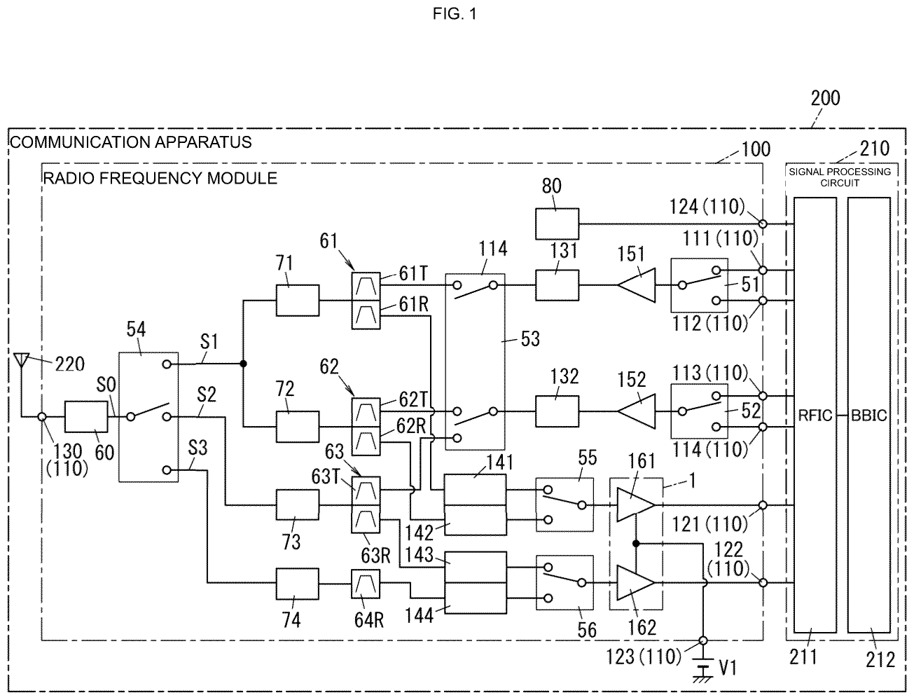

As illustrated in FIG. 1, a radio frequency module 100 according to an embodiment is provided in a communication apparatus 200, such as a portable terminal (a smartphone, a smartwatch, etc.), and used. The radio frequency module 100 converts a reception signal received by the communication apparatus 200 into a reception signal of a predetermined frequency band and amplifies the converted reception signal. The radio frequency module 100 also amplifies a transmission signal to be transmitted by the communication apparatus 200, converts the transmission signal into a transmission signal of a predetermined frequency band, and transmits the converted transmission signal. Thus, the radio frequency module 100 includes a plurality of amplifiers (power amplifiers 151 and 152 and low noise amplifiers 161 and 162) to amplify reception signals and transmission signals. In the radio frequency module 100, some of the plurality of amplifiers are integrated together as a semiconductor integrated circuit 1.

The semiconductor integrated circuit 1 mentioned above is arranged at a mounting substrate of the radio frequency module 100. The semiconductor integrated circuit 1 supplies a power supply voltage (power supply V1), which is supplied from the mounting substrate, to a plurality of amplifiers inside the semiconductor integrated circuit 1. Thus, the semiconductor integrated circuit 1 includes a power supply wiring unit to supply the power supply voltage, which is supplied from the mounting substrate, to the plurality of amplifiers inside the semiconductor integrated circuit 1. In this embodiment, the power supply wiring unit is routed in such a manner that electromagnetic interference with the plurality of amplifiers inside the semiconductor integrated circuit 1 can be suppressed. The radio frequency module 100 and the communication apparatus 200 will be described in detail below.

### (2) Configuration of Communication Apparatus

The communication apparatus 200 according to an embodiment will be described with reference to FIG. 1. The communication apparatus 200 is an example of a communication apparatus including the radio frequency module 100 according to this embodiment.

As illustrated in FIG. 1, the communication apparatus 200 is, for example, a portable terminal (for example, a smartphone) or a wearable terminal (for example, a smartwatch). The communication apparatus 200 includes the radio frequency module 100, a signal processing circuit 210, and an antenna 220.

The radio frequency module 100 is configured to extract and amplify a reception signal of a predetermined frequency band from among reception signals received at the antenna 220 and output the amplified reception signal to the signal processing circuit 210. The radio frequency module 100 is also configured to amplify a transmission signal output from the signal processing circuit 210, convert the transmission signal into a transmission signal of a predetermined frequency band, and output the converted transmission signal from the antenna 220.

The signal processing circuit 210 is connected to the radio frequency module 100 and is configured to perform signal processing for radio frequency signals. More particularly, the signal processing circuit 210 performs signal processing for a reception signal output from the radio frequency module 100 and signal processing for a transmission signal to be output to the radio frequency module 100. The signal processing circuit 210 includes an RF signal processing circuit 211 and a baseband signal processing circuit 212.

The RF signal processing circuit 211 is, for example, an RFIC (Radio Frequency Integrated Circuit). The RF signal processing circuit 211 is configured to perform signal processing, such as down-conversion, for a reception signal output from the radio frequency module 100 and output the processed reception signal to the baseband signal processing circuit 212. The RF signal processing circuit 211 is also configured to perform signal processing, such as up-conversion, for a transmission signal output from the baseband signal processing circuit 212 and output the processed transmission signal to the radio frequency module 100. The baseband signal processing circuit 212 is, for example, a BBIC (Baseband Integrated Circuit). The baseband signal processing circuit 212 is configured to output a reception signal output from the RF signal processing circuit 211 to the outside. The baseband signal processing circuit 212 is also configured to generate a transmission signal from a baseband signal (for example, an audio signal and an image signal) input from the outside and output the generated transmission signal to the RF signal processing circuit 211.

### (3) Circuit Configuration of Radio Frequency Module

An example of the circuit configuration of the radio frequency module 100 will be described with reference to FIG. 1. As illustrated in FIG. 1, the radio frequency module 100 includes, as circuit components, a plurality of external connection terminals 110, power amplifiers 151 and 152, low noise amplifiers 161 and 162, transmission filters 61T to 63T, reception filters 61R to 64R, output matching circuits 131 and 132, matching circuits 141 to 144, matching circuits 71 to 74, a matching circuit 60, switches 51 to 56, and a controller 80.

The plurality of external connection terminals 110 include an antenna terminal 130, four signal input terminals 111 to 114, two signal output terminals 121 and 122, a power supply input terminal 123, and an input terminal 124. The antenna terminal 130 is a terminal to which the antenna 220 is connected. The four signal input terminals 111 to 114 are terminals to which transmission signals from the signal processing circuit 210 are input and are connected to four output parts of the signal processing circuit 210. In this embodiment, a transmission signal of a transmission band of a first communication band is input to the signal input terminal 113. A transmission signal of a transmission band of a second communication band is input to the signal input terminal 114. A transmission signal of a transmission band of a third communication band is input to the signal input terminal 111. A transmission signal of a transmission band of a fourth communication band is input to the signal input terminal 112. The first communication band and the second communication band are, for example, different communication bands in a mid-band (for example, a band ranging from 1 GHZ to 6 GHz). The third communication band and the fourth communication band are, for example, different communication bands in a high-band (for example, a band of 24 GHz or higher).

The two signal output terminals 121 and 122 are terminals from which transmission signals from the radio frequency module 100 are output to the signal processing circuit 210 and are connected to the two input parts of the signal processing circuit 210. The power supply input terminal 123 is a terminal to which an output voltage of the power supply V1, which is provided in the communication apparatus 200, is input. The input terminal 124 is a terminal to which a control signal from the signal processing circuit 210 is input. The control signal input to the input terminal 124 is output to the controller 80.

The switch 51 includes a common terminal and two selection terminals (first selection terminal and second selection terminal). The common terminal of the switch 51 is connected to an input part of the power amplifier 151. The two selection terminals of the switch 51 are connected to corresponding output parts of the RF signal processing circuit 211 with the signal input terminals 111 and 112 interposed therebetween. The common terminal of the switch 51 is selectively connected to one of the two selection terminals of the switch 51. That is, the switch 51 selectively outputs to the input part of the power amplifier 151 one of transmission signals input to the two signal input terminals 111 and 112 from the RF signal processing circuit 211.

The switch 52 includes a common terminal and two selection terminals (first selection terminal and second selection terminal). The common terminal of the switch 52 is connected to an input part of the power amplifier 152. The two selection terminals of the switch 52 are connected to corresponding output parts of the RF signal processing circuit 211 with the signal input terminals 113 and 114 interposed therebetween. The common terminal of the switch 52 is selectively connected to one of the two selection terminals of the switch 52. Thus, the switch 52 selectively outputs to the input part of the power amplifier 152 one of two transmission signals input to the two signal input terminals 113 and 114 from the RF signal processing circuit 211.

The power amplifiers 151 and 152 each include an input part and an output part. The input parts of the power amplifiers 151 and 152 are connected to the common terminals of the switches 51 and 52, respectively. The output parts of the power amplifiers 151 and 152 are connected to common terminals, which will be described later, of the switch 53 with the output matching circuits 131 and 132 interposed therebetween, respectively. The power amplifiers 151 and 152 amplify transmission signals input from the switches 51 and 52, respectively, and output the amplified transmission signals to the common terminals of the switch 53 via the output matching circuits 131 and 132, respectively.

The switch 53 includes the two common terminals (first common terminal and second common terminal) and three selection terminals (first to third selection terminals). The first and second common terminals of the switch 53 are connected to the output parts of the power amplifiers 151 and 152 with the output matching circuits 131 and 132 interposed therebetween, respectively. The first to third selection terminals of the switch 53 are connected to input parts of the transmission filters 61T to 63T, respectively. The first common terminal of the switch 53 is selectively connected to one of the first to third selection terminals of the switch 53. Thus, the switch 53 selectively outputs an output signal of the output matching circuit 131 (that is, an output signal of the power amplifier 151) to any one of the transmission filters 61T to 63T. Furthermore, the second common terminal of the switch 53 is selectively connected to one of the first to third selection terminals of the switch 53. Thus, the switch 53 selectively outputs the output matching circuit 132 (that is, an output signal of the power amplifier 152) to any one of the transmission filters 61T to 63T.

The transmission filter 61T includes an input part and an output part. The input part of the transmission filter 61T is connected to the first selection terminal of the switch 53, and the output part of the transmission filter 61T is connected to a first selection terminal, which will be described later, of the switch 54 with the matching circuit 71 interposed therebetween. The transmission filter 61T allows a transmission signal of the transmission band of the first communication band to pass therethrough. The transmission filter 61T allows a transmission signal selected by the switch 53 from among transmission signals amplified by the power amplifiers 151 and 152 to pass therethrough. The transmission filter 62T includes an input part and an output part. The input part of the transmission filter 62T is connected to the second selection terminal of the switch 53, and the output part of the transmission filter 62T is connected to the first selection terminal, which will be described later, of the switch 54 with the matching circuit 72 interposed therebetween. The transmission filter 62T allows a transmission signal of the transmission band of the second communication band to pass therethrough. The transmission filter 62T allows a transmission signal selected by the switch 53 from among transmission signals amplified by the power amplifiers 151 and 152 to pass therethrough. The transmission filter 63T includes an input part and an output part. The input part of the transmission filter 63T is connected to the third selection terminal of the switch 53, and the output part of the transmission filter 63T is connected to a second selection terminal, which will be described later, of the switch 54 with the matching circuit 73 interposed therebetween. The transmission filter 63T allows a transmission signal of the transmission band of the third communication band to pass therethrough. The transmission filter 63T allows a transmission signal selected by the switch 53 from among transmission signals amplified by the power amplifiers 151 and 152 to pass therethrough.

The reception filter 61R includes an input part and an output part. The input part of the reception filter 61R is connected to the first selection terminal, which will be described later, of the switch 54 with the matching circuit 71 interposed therebetween. The output part of the reception filter 61R is connected to a first selection terminal, which will be described later, of the switch 55 with the matching circuit 141 interposed therebetween. The reception filter 61R allows a reception signal of the reception band of the first communication band from among reception signals output from the first selection terminal of the switch 54 to pass therethrough. The reception filter 62R includes an input part and an output part. The input part of the reception filter 62R is connected to the first selection terminal, which will be described later, of the switch 54 with the matching circuit 72 interposed therebetween. The output part of the reception filter 62R is connected to a second selection terminal, which will be described later, of the switch 55 with the matching circuit 142 interposed therebetween. The reception filter 62R allows a reception signal of the reception band of the second communication band from among reception signals output from the first selection terminal of the switch 54 to pass therethrough.

The reception filter 63R includes an input part and an output part. The input part of the reception filter 63R is connected to the second selection terminal, which will be described later, of the switch 54 with the matching circuit 73 interposed therebetween. The output part of the reception filter 63R is connected to a first selection terminal, which will be described later, of the switch 56 with the matching circuit 143 interposed therebetween. The reception filter 63R allows a reception signal of the reception band of the third communication band from among reception signals output from the second selection terminal of the switch 54 to pass therethrough. The reception filter 64R includes an input part and an output part. The input part of the reception filter 64R is connected to a third selection terminal, which will be described later, of the switch 54 with the matching circuit 74 interposed therebetween. The output part of the reception filter 64R is connected to a second selection terminal, which will be described later, of the switch 56 with the matching circuit 144 interposed therebetween. The reception filter 64R allows a reception signal of the reception band of the fourth communication band from among reception signals output from the third selection terminal of the switch 54 to pass therethrough.

In this embodiment, the transmission filter 61T and the reception filter 61R form a duplexer 61. The transmission filter 62T and the reception filter 62R form a duplexer 62. The transmission filter 63T and the reception filter 63R form a duplexer 63.

The switch 55 includes a common terminal and the two selection terminals (first and second selection terminals). The common terminal of the switch 55 is connected to an input part of the low noise amplifier 161. The selection terminals of the switch 55 are connected to the output parts of the reception filters 61R and 62R with the matching circuits 141 and 142 interposed therebetween, respectively. The common terminal of the switch 55 is selectively connected to one of the two selection terminals of the switch 55. Thus, the switch 55 selectively outputs to the input part of the low noise amplifier 161 one of output signals of the matching circuits 141 and 142 (that is, output signals of the reception filters 61R and 62R).

The switch 56 includes a common terminal and the two selection terminals (first and second selection terminals). The common terminal of the switch 56 is connected to an input part of the low noise amplifier 162. The selection terminals of the switch 56 are connected to the output parts of the reception filters 63R and 64R with the matching circuits 143 and 144 interposed therebetween, respectively. The common terminal of the switch 56 is selectively connected to one of the two selection terminals of the switch 56. Thus, the switch 56 selectively outputs to the input part of the low noise amplifier 162 one of output signals of the matching circuits 143 and 144 (that is, output signals of the reception filters 63R and 64R).

The low noise amplifiers 161 and 162 each include an input part and an output part. The input parts of the low noise amplifiers 161 and 162 are connected to the common terminals of the switches 55 and 56, respectively. The output parts of the low noise amplifiers 161 and 162 are connected to input parts of the RF signal processing circuit 211 with the signal output terminals 121 and 122 interposed therebetween, respectively. The low noise amplifiers 161 and 162 amplify reception signals output from the switches 55 and 56, respectively, and output the amplified reception signals to the input parts of the RF signal processing circuit 211 via the signal output terminals 121 and 122, respectively.

The switch 54 is an antenna switch. The switch 54 is a switch that allows switching between connection and disconnection between a signal path SO to the antenna terminal 130 and a plurality of signal paths Si to S3 to the duplexers 61 to 63 and the reception filter 64R. The switch 54 includes, for example, a common terminal and the three selection terminals (first to third selection terminals). The common terminal of the switch 54 is connected to the antenna terminal 130 with the matching circuit 60 interposed therebetween. The first selection terminal of the switch 54 is connected to the duplexers 61 and 62 with the matching circuits 71 and 72 interposed therebetween, respectively. The second selection terminal of the switch 54 is connected to the duplexer 63 with the matching circuit 73 interposed therebetween. The third selection terminal of the switch 54 is connected to the reception filter 64T with the matching circuit 74 interposed therebetween. The common terminal of the switch 54 is selectively connected to one of the three selection terminals of the switch 54. The switch 54 is capable of one-to-one connection and one-to-many connection. Thus, the switch 54 outputs a reception signal received at the antenna 220 to one or a plurality of reception filters out of the reception filters 61R to 64R. Furthermore, the switch 54 outputs one or a plurality of output signals out of output signals of the transmission filters 61T to 63T to the antenna terminal 130.

The matching circuit 60 is connected between the antenna terminal 130 and the common terminal of the switch 54 and achieves impedance matching between the antenna 220 and the switch 54.

The matching circuits 71 and 72 are connected between the first selection terminal of the switch 54 and the duplexers 61 and 62, respectively, and achieve impedance matching between the switch 54 and the duplexers 61 and 62, respectively. The matching circuit 73 is connected between the second selection terminal of the switch 54 and the duplexer 63 and achieves impedance matching between the switch 54 and the duplexer 63. The matching circuit 74 is connected between the third selection terminal of the switch 54 and the reception filter 64R and achieves impedance matching between the switch 54 and the reception filter 64R.

The output matching circuit 131 is connected between the output part of the power amplifier 151 and the first common terminal of the switch 53 and achieves impedance matching between the power amplifier 151 and the transmission filters 61T to 63T. The output matching circuit 132 is connected between the output part of the power amplifier 152 and the second common terminal of the switch 53 and achieves impedance matching between the power amplifier 152 and the transmission filters 61T to 63T. The output matching circuits 131 and 132 include, for example, a transformer.

The matching circuit 141 is connected between the output part of the reception filter 61R and the first selection terminal of the switch 55 and achieves impedance matching between the reception filter 61R and the switch 55. The matching circuit 142 is connected between the output part of the reception filter 62R and the second selection terminal of the switch 55 and achieves impedance matching between the reception filter 61R and the switch 55. The matching circuit 143 is connected between the output part of the reception filter 63R and the first selection terminal of the switch 56 and achieves impedance matching between the reception filter 63R and the switch 56. The matching circuit 144 is connected between the output part of the reception filter 64R and the second selection terminal of the switch 56 and achieves impedance matching between the reception filter 64R and the switch 56. The matching circuits 141 to 144 each include, for example, an inductor.

The controller 80 controls the power amplifiers 151 and 152, the low noise amplifiers 161 and 162, the switches 53 to 56, and so on in accordance with control signals input from the RF signal processing circuit 211 to the input terminal 124.

The radio frequency module 100 includes, as a circuit component, the semiconductor integrated circuit 1. The semiconductor integrated circuit 1 includes, for example, the low noise amplifiers 161 and 162. That is, the low noise amplifiers 161 and 162 are integrated together as the semiconductor integrated circuit 1. The semiconductor integrated circuit 1 receives the power supply voltage supplied from the power supply input terminal 123 and supplies the received power supply voltage to the low noise amplifiers 161 and 162.

### (4) Structure of Radio Frequency Module

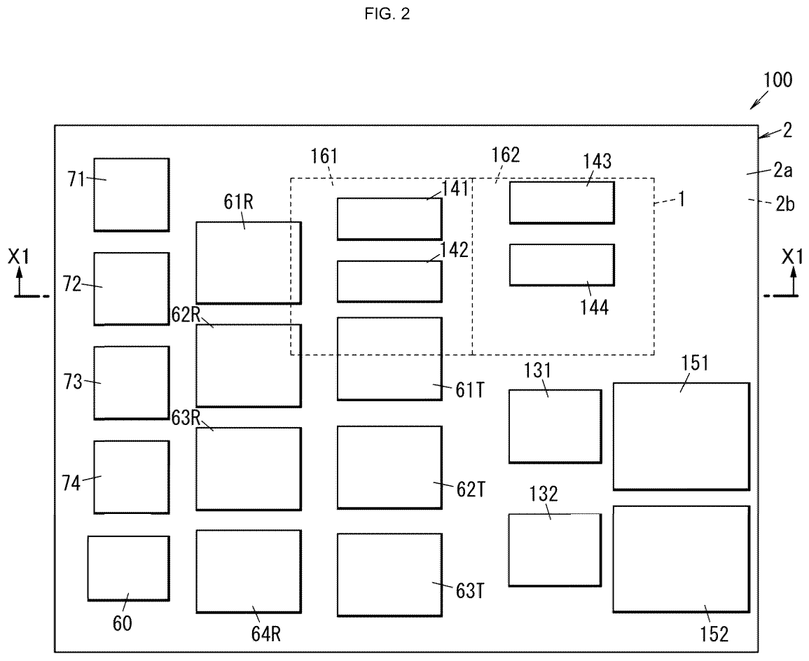

An example of the structure of the radio frequency module 100 will be described with reference to FIGS. 2 to 4.

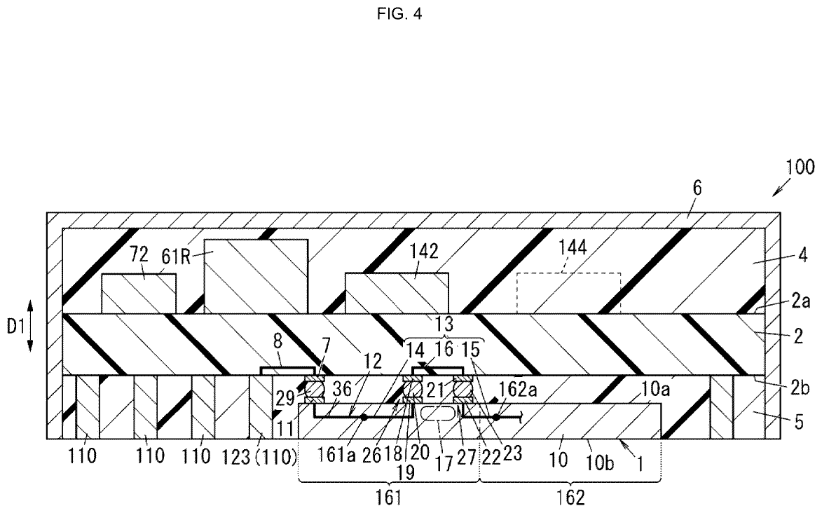

As illustrated in FIG. 4, the radio frequency module 100 further includes, in addition to the plurality of circuit components described above, a mounting substrate 2, a first resin layer 4, a second resin layer 5, and a shield layer 6.

The mounting substrate 2 is a circuit substrate at which the plurality of circuit components described above are arranged and has, for example, a rectangular plate shape. The mounting substrate 2 is, for example, a multilayer substrate including a plurality of dielectric layers and a plurality of conductive layers. The plurality of dielectric layers and the plurality of conductive layers are laminated in a thickness direction D1 of the mounting substrate 2. The plurality of conductive layers are formed in patterns set for the individual layers. The plurality of conductive layers include a ground layer maintained at the ground potential. The mounting substrate 2 has a first main surface 2a and a second main surface 2b that are opposite to each other in the thickness direction D1 of the mounting substrate 2.

The plurality of circuit components described above are disposed on the first main surface 2a or the second main surface 2b of the mounting substrate 2. More particularly, as illustrated in FIG. 2, out of the plurality of circuit components described above, the power amplifiers 151 and 152, the transmission filters 61T to 63T, the reception filters 61R to 64R, the output matching circuits 131 and 132, the matching circuits 141 to 144, the matching circuits 71 to 74, and the matching circuit 60 are disposed on the first main surface 2a of the mounting substrate 2.

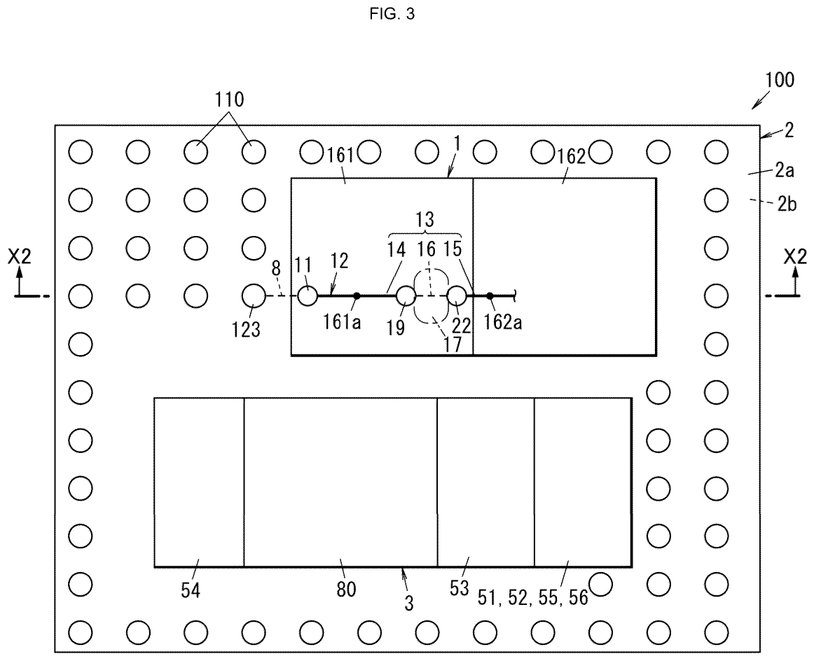

Furthermore, as illustrated in FIG. 3, out of the plurality of circuit components described above, the semiconductor integrated circuit 1 (low noise amplifiers 161 and 162), the switches 51 to 56, the controller 80, and the plurality of external connection terminals 110 are disposed on the second main surface 2b of the mounting substrate 2. The switches 51 to 56 and the controller 80 are integrated together as a semiconductor integrated circuit 3. That is, the radio frequency module 100 includes the semiconductor integrated circuit 3 including the switches 51 to 56 and the controller 80.

In this embodiment, the matching circuits 71 to 74 are arranged to overlap with the semiconductor integrated circuit 1 in plan view from the thickness direction D1 of the mounting substrate 2 (see FIG. 2). More particularly, the matching circuits 71 and 72 are arranged to overlap with the low noise amplifier 161 in plan view from the thickness direction D1 of the mounting substrate 2. Furthermore, the matching circuits 73 and 74 are arranged to overlap with the low noise amplifier 162 in plan view from the thickness direction D1 of the mounting substrate 2. The state in which “a matching circuit overlaps with a semiconductor integrated circuit in plan view from the thickness direction D1 of the mounting substrate 2” includes a case where the entire matching circuit overlaps with the semiconductor integrated circuit in plan view from the thickness direction D1 of the mounting substrate 2 and a case where part of the matching circuit overlaps with the semiconductor integrated circuit.

As described above, by arranging the matching circuits 71 to 74 to overlap with the semiconductor integrated circuit 1 in plan view from the thickness direction D1 of the mounting substrate 2, the length of a connection wiring unit that connects the semiconductor integrated circuit 1 (more particularly, the low noise amplifiers 161 and 162) to the matching circuits 71 to 74 can be reduced. By shortening the connection wiring unit, entry of noise into the connection wiring unit can be suppressed.

As illustrated in FIG. 4, the first resin layer 4 is disposed on the first main surface 2a of the mounting substrate 2. The first resin layer 4 covers outer surfaces (including top surfaces and outer peripheral surfaces) of a plurality of circuit components disposed on the first main surface 2a of the mounting substrate 2. A “top surface of a circuit component” represents a main surface of the circuit component that is far from the mounting substrate 2. The first resin layer 4 seals the plurality of circuit components. The second resin layer 5 is disposed on the second main surface 2b of the mounting substrate 2. The second resin layer 5 covers outer surfaces except the top surfaces of a plurality of circuit components mounted on the second main surface 2b of the mounting substrate 2. The second resin layer 5 seals the plurality of circuit components. More particularly, front end surfaces (top surfaces) of the plurality of external connection terminals 110 are exposed out of the second resin layer 5, and the other surfaces of the plurality of external connection terminals 110 are covered with the second resin layer 5. Top surfaces of the semiconductor integrated circuits 1 and 3 (in FIG. 4, only the semiconductor integrated circuit 1 is illustrated) are exposed out of the second resin layer 5, and the other surfaces of the semiconductor integrated circuits 1 and 3 are covered with the second resin layer 5. The first resin layer 4 and the second resin layer 5 include resin. The first resin layer 4 and the second resin layer 5 may also include fillers. A material of the second resin layer 5 may be the same as a material of the first resin layer 4 or may be different from the material of the first resin layer 4.

The shield layer 6 is, for example, made of metal. The shield layer 6 is arranged to cover outer surfaces (including outer peripheral surfaces and a top surface) of the first resin layer 4, outer peripheral surfaces of the second resin layer 5, and outer peripheral surfaces of the mounting substrate 2. The top surface of the second resin layer 5 is exposed out of the shield layer 6. The “top surface of the second resin layer 5” represents a main surface of the second resin layer 5 that is far from the mounting substrate 2. The shield layer 6 is connected to the ground layer of the mounting substrate 2. Thus, the shield layer 6 is maintained at the ground potential.

### (5) Routing Structure of Power Supply Wiring Unit 12 Inside Semiconductor Integrated Circuit 1

Routing of the power supply wiring unit 12 inside the semiconductor integrated circuit 1 will be described with reference to FIG. 4. In the semiconductor integrated circuit 1, the power supply wiring unit 12 supplies the power supply voltage, which is supplied from the mounting substrate 2, to an amplifier (in this embodiment, the low noise amplifiers 161 and 162) inside the semiconductor integrated circuit 1. Here, the power supply wiring unit 12 is routed to make a detour towards the mounting substrate 2 from the semiconductor integrated circuit 1 in such a manner that a specific part 17 of an amplifier inside the semiconductor integrated circuit 1 is bypassed. The routing structure of the power supply wiring unit 12 will be described in detail below.

The radio frequency module 100 further includes a power supply electrode 7, a power supply wiring unit 8, and the power supply wiring unit 12, in addition to the mounting substrate 2, the power supply input terminal 123, and the semiconductor integrated circuit 1 described above. Furthermore, the semiconductor integrated circuit 1 includes a circuit substrate 10 and a power supply electrode 11, in addition to the low noise amplifiers 161 and 162 described above. Each of the low noise amplifiers 161 and 162 is an example of an amplifier included in the semiconductor integrated circuit 1.

The power supply input terminal 123 is connected to the power supply V1 of the communication apparatus 200, and the power supply voltage of the power supply V1 from the communication apparatus 200 is input to the power supply input terminal 123. The power supply input terminal 123 is disposed on the second main surface 2b of the mounting substrate 2. The power supply electrode 7 is an electrode for supplying the power supply voltage to the semiconductor integrated circuit 1 and is disposed on the second main surface 2b of the mounting substrate 2. The power supply wiring unit 8 is a conductive path that connects the power supply input terminal 123 to the power supply electrode 7 and is provided inside the mounting substrate 2 or on a surface of the mounting substrate 2.

The circuit substrate 10 is a circuit substrate at which circuit components forming the semiconductor integrated circuit 1 are provided. The circuit substrate 10 has a first main surface 10a and a second main surface 10b that are opposite to each other in the thickness direction D1. The first main surface 10a of the circuit substrate 10 is a main surface that faces the second main surface 2b of the mounting substrate 2.

The power supply electrode 11 is an electrode to which the power supply voltage, which is supplied from the power supply electrode 7 of the mounting substrate 2, is input and is disposed on the first main surface 10a of the circuit substrate 10. The power supply electrode 11 is connected to the power supply electrode 7 with a connection conductor 29 interposed therebetween. In the example of FIG. 4, the connection conductor 29 is a solder bump. However, the connection conductor 29 may be bonding wire.

The low noise amplifier 161 includes a first power supply terminal 161a. The first power supply terminal 161a is a terminal through which the power supply voltage supplied from the power supply electrode 11 is input to the low noise amplifier 161. The first power supply terminal 161a is, for example, disposed on the first main surface 10a of the circuit substrate 10. The low noise amplifier 162 includes a second power supply terminal 162a. The second power supply terminal 162a is a terminal through which the power supply voltage supplied from the power supply electrode 11 is input to the low noise amplifier 162. The second power supply terminal 162a is, for example, disposed on the first main surface 10a of the circuit substrate 10.

The power supply wiring unit 12 is a conductive path for allowing the power supply voltage input to the power supply electrode 11 to be supplied to the first power supply terminal 161a and the second power supply terminal 162a. The power supply wiring unit 12 connects the power supply electrode 11 to the first power supply terminal 161a and the second power supply terminal 162a.

The power supply wiring unit 12 includes an terminal-to-terminal wiring part 13. The terminal-to-terminal wiring part 13 is a wiring part of the power supply wiring unit 12 and connects the first power supply terminal 161a to the second power supply terminal 162a.

The terminal-to-terminal wiring part 13 includes a first circuit-side wiring part 14, a second circuit-side wiring part 15, and a substrate-side wiring part 16. Furthermore, the radio frequency module 100 includes a first connection member 26 and a second connection member 27.

The first circuit-side wiring part 14 and the second circuit-side wiring part 15 are parts of the terminal-to-terminal wiring part 13 and are arranged in the semiconductor integrated circuit 1. The substrate-side wiring part 16 is a part of the terminal-to-terminal wiring part 13 and is arranged at the mounting substrate 2. That is, at least part (substrate-side wiring part 16) of the terminal-to-terminal wiring part 13 is arranged to make a detour towards the mounting substrate 2 from the semiconductor integrated circuit 1.

The first circuit-side wiring part 14, the second circuit-side wiring part 15, and the substrate-side wiring part 16 are, for example, connected in series. More particularly, each of the first circuit-side wiring part 14, the second circuit-side wiring part 15, and the substrate-side wiring part 16 includes a first end and a second end in the longitudinal direction thereof. The first end of the first circuit-side wiring part 14 is connected to the first power supply terminal 161a. The second end of the first circuit-side wiring part 14 is connected to the first end of the substrate-side wiring part 16 with the first connection member 26 interposed therebetween. That is, the first circuit-side wiring part 14 is connected between the substrate-side wiring part 16 and the first power supply terminal 161a. The second end of the substrate-side wiring part 16 is connected to the first end of the second circuit-side wiring part 15 with the second connection member 27 interposed therebetween. The second end of the second circuit-side wiring part 15 is connected to the second power supply terminal 162a. That is, the second circuit-side wiring part 15 is connected between the substrate-side wiring part 16 and the second power supply terminal 162a.

The first connection member 26 is a conductor member that electrically connects the second end of the first circuit-side wiring part 14 to the first end of the substrate-side wiring part 16. The first connection member 26 is disposed between the second main surface 2b of the mounting substrate 2 and the first main surface 10a of the semiconductor integrated circuit 1. The first connection member 26 includes an electrode 18, an electrode 19, and a first connection conductor 20. The electrode 18 is provided on the second main surface 2b of the mounting substrate 2 and is connected to the first end of the substrate-side wiring part 16. The electrode 19 is provided on the first main surface 10a of the semiconductor integrated circuit 1 and is connected to the second end of the first circuit-side wiring part 14. The first connection conductor 20 is a conductor that connects the electrode 18 to the electrode 19. In the example of FIG. 4, the first connection conductor 20 is a solder bump. However, the first connection conductor 20 may be bonding wire.

The second connection member 27 is a conductor member that electrically connects the first end of the second circuit-side wiring part 15 to the second end of the substrate-side wiring part 16. The second connection member 27 is disposed between the second main surface 2b of the mounting substrate 2 and the first main surface 10a of the semiconductor integrated circuit 1. The second connection member 27 includes an electrode 21, an electrode 22, and a second connection conductor 23. The electrode 21 is provided on the second main surface 2b of the mounting substrate 2 and is connected to the second end of the substrate-side wiring part 16. The electrode 22 is provided on the first main surface 10a of the semiconductor integrated circuit 1 and is connected to the first end of the second circuit-side wiring part 15. The second connection conductor 23 is a conductor that connects the electrode 21 to the electrode 22. In the example of FIG. 4, the second connection conductor 23 is a solder bump. However, the second connection conductor 23 may be bonding wire.

The semiconductor integrated circuit 1 includes the specific part 17 that needs to avoid being electromagnetically affected by the power supply wiring unit 12. The specific part 17 is an RF (Radio Frequency) part of an amplifier (for example, the low noise amplifiers 161 and 162) inside the semiconductor integrated circuit 1. The “RF part” represents a part through which a reception signal (radio frequency signal) flows, and the “RF part” is susceptible to external electromagnetic influences. The substrate-side wiring part 16 is a part of the terminal-to-terminal wiring part 13 and overlaps with the specific part 17 of the semiconductor integrated circuit 1 in plan view from the thickness direction D1 of the mounting substrate 2. That is, the substrate-side wiring part 16 is a part that makes a detour towards the mounting substrate 2 from the semiconductor integrated circuit 1 to bypass the specific part 17 of the semiconductor integrated circuit 1. “Make a detour towards the mounting substrate 2 from the semiconductor integrated circuit 1” represents starting from the semiconductor integrated circuit 1, passing through the mounting substrate 2 side, and returning to the semiconductor integrated circuit 1. With the substrate-side wiring part 16, the space between the terminal-to-terminal wiring part 13 and the specific part 17 of the semiconductor integrated circuit 1 can be ensured. As a result, a situation where the terminal-to-terminal wiring part 13 electromagnetically interferes with the specific part 17 of the semiconductor integrated circuit 1 can be suppressed.

The power supply wiring unit 12 includes a wiring part 36 (a wiring part that connects the power supply electrode 11 to the first power supply terminal 161a), which is different from the terminal-to-terminal wiring part 13. The wiring part 36 is arranged at the circuit substrate 10 of the semiconductor integrated circuit 1. However, only at least part of the wiring part 36 needs to be arranged at the circuit substrate 10. That is, part of the wiring part 36 may be arranged at the mounting substrate 2, like the substrate-side wiring part 16.

### (6) Relationship Between Number of Connection Members and Number of Amplifiers

The relationship between the number of connection members and the number of amplifiers will be described with reference to FIG. 4. The “connection members”, such as the first connection member 26 and the second connection member 27, are provided between the second main surface 2b of the mounting substrate 2 and the first main surface 10a of the semiconductor integrated circuit 1 and are conductor members for electrically connecting one end of the substrate-side wiring part 16 to one end of one of the first circuit-side wiring part 14 and the second circuit-side wiring part 15. The “amplifiers”, such as the low noise amplifiers 161 and 162, are amplifiers included in the semiconductor integrated circuit 1.

As illustrated in FIG. 4, for each detour of the terminal-to-terminal wiring part 13 towards the mounting substrate 2 from the semiconductor integrated circuit 1, one connection member for going towards the mounting substrate 2 and one connection member for coming back towards the semiconductor integrated circuit 1, that is, two connection members (first connection member 26 and second connection member 27) in total, are provided between the mounting substrate 2 and the semiconductor integrated circuit 1.

In this embodiment, the terminal-to-terminal wiring part 13 makes only one detour towards the mounting substrate 2 from the semiconductor integrated circuit 1. Thus, two connection members (first connection member 26 and second connection member 27) are provided between the mounting substrate 2 and the semiconductor integrated circuit 1.

Although the terminal-to-terminal wiring part 13 makes only one detour towards the mounting substrate 2 from the semiconductor integrated circuit 1 in this embodiment, the terminal-to-terminal wiring part 13 may make multiple detours towards the mounting substrate 2 from the semiconductor integrated circuit 1. In this case, the number of the connection members is equal to the number obtained by doubling the number of detours towards the mounting substrate 2 from the semiconductor integrated circuit 1 that the terminal-to-terminal wiring part 13 makes. As described above, in the case where the terminal-to-terminal wiring part 13 makes multiple detours towards the mounting substrate 2 from the semiconductor integrated circuit 1, many (multiple) connection conductors are provided between the mounting substrate 2 and the semiconductor integrated circuit 1. The number of the multiple connection members is greater than the number of the amplifiers (in this embodiment, the low noise amplifiers 161 and 162) included in the semiconductor integrated circuit 1.

That is, in the case where the number of the connection conductors between the mounting substrate 2 and the semiconductor integrated circuit 1 is greater than the number of the amplifiers included in the semiconductor integrated circuit 1, the terminal-to-terminal wiring part 13 is highly likely to make a detour (detours) towards the mounting substrate 2 from the semiconductor integrated circuit 1. In other words, the terminal-to-terminal wiring part 13 is highly likely to include at least one substrate-side wiring part 16.

### (7) Effects

The radio frequency module 100 according to this embodiment includes the mounting substrate 2, the semiconductor integrated circuit 1, and the power supply wiring unit 12. The semiconductor integrated circuit 1 is arranged at the mounting substrate 2. The semiconductor integrated circuit 1 includes the low noise amplifier 161 (first amplifier), the low noise amplifier 162 (second amplifier), and the power supply electrode 11. The low noise amplifier 161 includes the first power supply terminal 161a. The low noise amplifier 162 includes the second power supply terminal 162a. A power supply voltage from the mounting substrate 2 is input to the power supply electrode 11. The power supply wiring unit 12 is a wiring unit that allows the power supply voltage to be supplied from the power supply electrode 11 to the first power supply terminal 161a and the second power supply terminal 162a. The power supply wiring unit 12 includes the terminal-to-terminal wiring part 13 that connects the first power supply terminal 161a to the second power supply terminal 162a. The terminal-to-terminal wiring part 13 includes the substrate-side wiring part 16 that is arranged at the mounting substrate 2.

With this arrangement, the terminal-to-terminal wiring part 13 includes the substrate-side wiring part 16. With the substrate-side wiring part 16, the space between the terminal-to-terminal wiring part 13 and the specific part 17 of an amplifier (for example, the low noise amplifier 161) inside the semiconductor integrated circuit 1 can be ensured. As a result, a situation where the terminal-to-terminal wiring part 13 electromagnetically interferes with the specific part 17 of the amplifier inside the semiconductor integrated circuit 1 can be suppressed. That is, the situation where the power supply wiring unit 12 electromagnetically interferes with the amplifier (for example, the low noise amplifier 161) inside the semiconductor integrated circuit 1 can be suppressed.

Furthermore, the communication apparatus 200 according to this embodiment includes the radio frequency module 100 and the signal processing circuit 210. The signal processing circuit 210 is connected to the radio frequency module 100 and performs signal processing for radio frequency signals. With this arrangement, a communication apparatus including a radio frequency module having the operational effects described above can be provided.

### (8) Modifications

Modifications of the radio frequency module 100 according to the embodiment described above will be described below. The embodiment described above may be combined with a modification described below. In the description provided below, the same components as those in the embodiment described above will be denoted by the same signs, and description of the same components will be omitted. Only components different from those in the embodiment described above may be described.

### (First Modification)

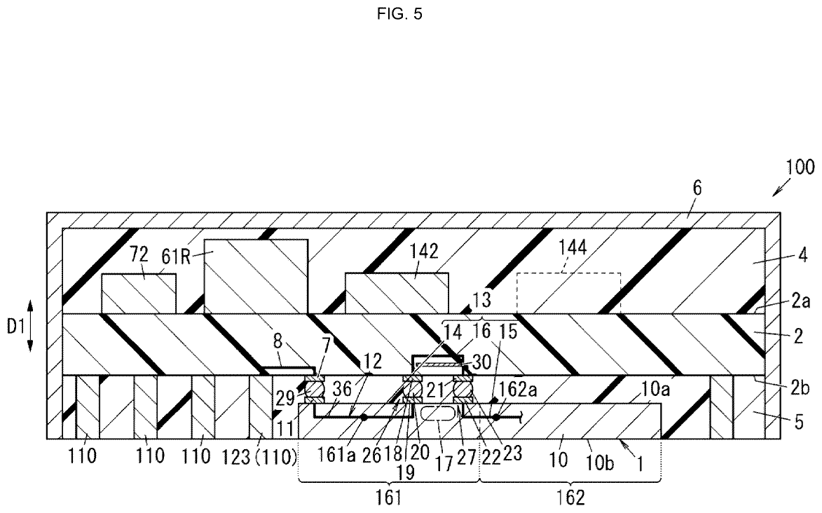

As illustrated in FIG. 5, the radio frequency module 100 according to a first modification includes a ground layer 30 provided at the mounting substrate 2 in the radio frequency module 100 according to the embodiment described above. The ground layer 30 is a conductor layer maintained at the ground potential. The ground layer 30 is disposed between the substrate-side wiring part 16 and the semiconductor integrated circuit 1 in the thickness direction D1 of the mounting substrate 2. In the example of FIG. 5, the ground layer 30 is arranged inside the mounting substrate 2. However, the ground layer 30 may be disposed on the second main surface 2b of the mounting substrate 2.

With this arrangement, the ground layer 30 can be disposed between the substrate-side wiring part 16 and the specific part 17 of an amplifier (for example, the low noise amplifier 161) inside the semiconductor integrated circuit 1. With the ground layer 30, the situation where the terminal-to-terminal wiring part 13 electromagnetically interferes with the specific part 17 of the amplifier inside the semiconductor integrated circuit 1 can further be suppressed.

### (Second Modification)

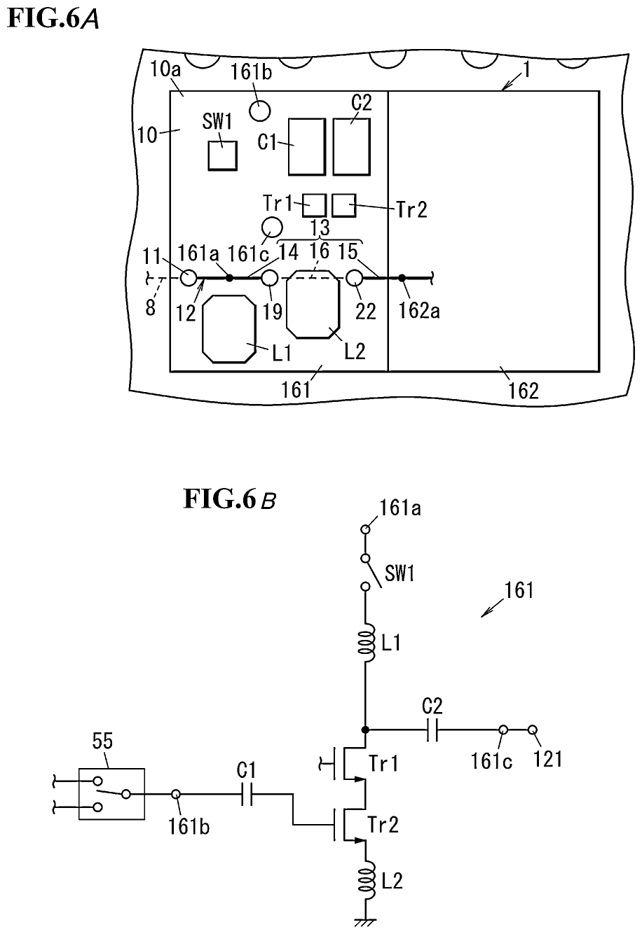

As illustrated in FIG. 6A, in a second modification, the substrate-side wiring part 16 overlaps with an inductor (for example, an inductor L2) of the low noise amplifier 161 in plan view from the thickness direction D1 of the mounting substrate 2. The second modification will be described in detail below.

As illustrated in FIG. 6B, the low noise amplifier 161 according to the second modification includes, as circuit components, the first power supply terminal 161a, an input part 161b, an output part 161c, the switch SW1, inductors L1 and L2, transistors Tr1 and Fr2 (amplifier elements), and capacitors C1 and C2. Each of the transistors Tr1 and Tr2 is, for example, an IGBT (Insulated Gate Bipolar Transistor). The transistors Tr1 and Tr2 are not necessarily IGBTs and may be bipolar transistors or MOSFETs. The transistors Tr1 and Tr2 each include a first electrode (collector), a second electrode (emitter), and a third electrode (gate).

The first electrode of the transistor Tr1 is connected to the first power supply terminal 161a with the inductor L1 and the switch SW1 interposed therebetween. The second electrode of the transistor Tr1 is connected to the first electrode of the transistor Tr2. The third electrode of the transistor Tr1 is connected to the controller 80 (see FIG. 1). The first electrode of the transistor Tr2 is connected to the second electrode of the transistor Tr1. The second electrode of the transistor Tr2 is connected to the ground with the inductor 12 interposed therebetween. The third electrode of the transistor Tr2 is connected to the input part 161b with the capacitor C1 interposed therebetween. That is, the transistor Tr2 is connected between the first power supply terminal 161a and the ground. The input part 161b is an input part to which an output signal from the common terminal of the switch 55 is input. The input part 161b is connected to the third electrode of the transistor Tr2 with the capacitor C1 interposed therebetween. The output part 161c is an output part through which an output signal of the low noise amplifier 161 is output and is connected to the signal output terminal 121 of the radio frequency module 100. The output part 161c is connected to the first electrode of the transistor Tr1 with the capacitor C2 interposed therebetween. The switch SW1 and the transistor Tr1 are controlled by the controller 80.

In the low noise amplifier 161, assuming a reception signal (input signal) is input to the input part 161b, the transistor Tr2 as an amplifier element becomes conductive so that a current corresponding to the reception signal passes through the transistor Tr2 and flows from the first power supply terminal 161a to the ground. The voltage of the first terminal (collector) of the transistor Tr1 at the time of conduction is output, as an amplification signal with respect to the reception signal, from the output part 161c. In the second modification, the transistor Tr2 functions as an amplifier element for amplifying a signal to be amplified (reception signal mentioned above) input to the input part 161b and outputting the amplified signal from the output part 161c.

As illustrated in FIG. 6A, the semiconductor integrated circuit 1 includes the low noise amplifiers 161 and 162. In the example of FIG. 6A, in the semiconductor integrated circuit 1, for example, the low noise amplifiers 161 and 162 are arranged in this order from the left to the right on the plane of drawing. Furthermore, the circuit components mentioned above of the low noise amplifier 161 are disposed in a specific arrangement on the first main surface 10a of the circuit substrate 10 of the semiconductor integrated circuit 1. In FIG. 6A, illustration of the arrangement of the circuit components of the low noise amplifier 162 other than the second power supply terminal 162a is omitted. Sign 8 in FIG. 6A represents a power supply wiring unit provided at the mounting substrate 2. Sign 16 in FIG. 6A represents a substrate-side wiring part provided at the mounting substrate 2. Signs 14 and 15 in FIG. 6A represent a first circuit-side wiring part and a second circuit-side wiring part that are provided on the first main surface 10a of the circuit substrate 10.

In the second modification, the inductor L2 is disposed between the first power supply terminal 161a and the second power supply terminal 162a. A part of the terminal-to-terminal wiring part 13, which connects the first power supply terminal 161a to the second power supply terminal 162a, that overlaps with the inductor L2 is arranged, as the substrate-side wiring part 16, to make a detour towards the mounting substrate 2 from the semiconductor integrated circuit 1. That is, the substrate-side wiring part 16 is arranged at the mounting substrate 2 in such a manner that the substrate-side wiring part 16 and the inductor L2 overlap in plan view from the thickness direction D1 of the mounting substrate 2. With the substrate-side wiring part 16, the space between the terminal-to-terminal wiring part 13 and the inductor L2 can be ensured. As a result, a situation where the inductor L2 is electromagnetically interfered with by the terminal-to-terminal wiring part 13 can be suppressed.

In the second modification, the low noise amplifier 162 is arranged similarly to the low noise amplifier 161. In the second modification, the terminal-to-terminal wiring part 13 overlaps with the inductor L2 of the low noise amplifier 161, out of the low noise amplifiers 161 and 162. However, the terminal-to-terminal wiring part 13 may overlap with the inductors L2 of both the low noise amplifiers 161 and 162. In this case, the substrate-side wiring part 16 is arranged at the mounting substrate 2 in such a manner that the substrate-side wiring part 16 and the inductors L2 of both the low noise amplifiers 161 and 162 overlap. A single substrate-side wiring part 16 may overlap with the inductors L2 of both the low noise amplifiers 161 and 162 or two substrate-side wiring parts 16 may individually overlap with the inductors L2 of the corresponding low noise amplifiers 161 and 162. In this case, the terminal-to-terminal wiring part 13 is arranged to make two detours in total in such a manner that, for each inductor L2, the terminal-to-terminal wiring part 13 makes a detour towards the mounting substrate 2 from the semiconductor integrated circuit 1.

### (Third Modification)

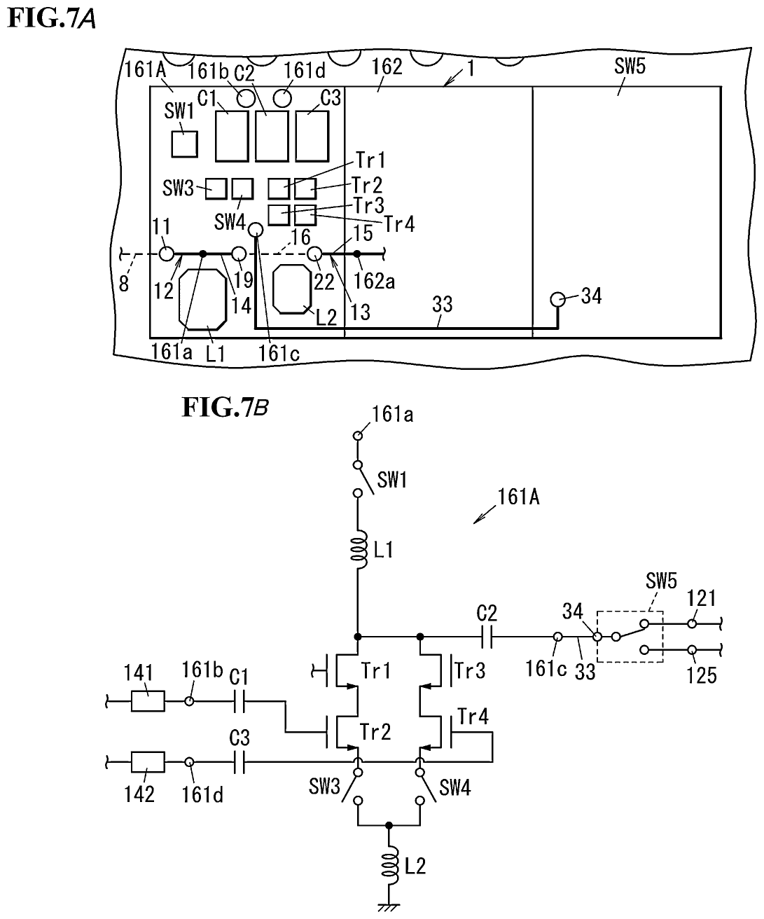

As illustrated in FIG. 7A, in a third modification, the substrate-side wiring part 16 overlaps with a connection wiring unit 33 of the semiconductor integrated circuit 1 in plan view from the thickness direction D1 of the mounting substrate 2. The connection wiring unit 33 is a conductive path that connects the output part 161c of the low noise amplifier 161 to an input part 34 of a switch SW5. The third modification will be described in detail below.

As illustrated in FIG. 7B, the semiconductor integrated circuit 1 according to the third modification is different from the semiconductor integrated circuit 1 according to the second modification (see FIG. 6B) in that the low noise amplifier 161 that includes a single input part 161b (see FIG. 6B) is replaced with a low noise amplifier 161A that includes a plurality of input parts 161b and 161d (see FIG. 7B) and that the semiconductor integrated circuit 1 further includes the switch SW5 and the connection wiring unit 33.

The low noise amplifier 161A according to the third modification further includes, as circuit components, the input part 161d, transistors Tr3 and Tr4 (amplifier elements), switches SW3 and SW4, and a capacitor C3, in addition to the circuit components of the low noise amplifier 161 according to the second modification (see FIG. 6B). The transistors Tr3 and TR4 are, for example, IGBTs and each include a first electrode (collector), a second electrode (emitter), and a third electrode (gate). The transistors Tr3 and Tr4 are not necessarily IGBTs and may be bipolar transistors or MOSFETS.

The switch SW3 is connected between the transistor Tr2 and the inductor L2. The first electrode of the transistor Tr3 is connected to the first power supply terminal 161a with the inductor L1 and the switch SW1 interposed therebetween. The second electrode of the transistor Tr3 is connected to the first electrode of the transistor Tr4. The third electrode of the transistor Tr3 is connected to the controller 80 (see FIG. 1). The second electrode of the transistor Tr4 is connected to the ground with the switch SW4 and the inductor L2 interposed therebetween. The third electrode of the transistor Tr4 is connected to the input part 161d with the capacitor C3 interposed therebetween. That is, the transistor Tr4 is connected between the first power supply terminal 161a and the ground. A series circuit including the transistors Tr1 and Tr2 and the switch SW3 and a series circuit including the transistors Tr3 and Tr4 and the switch SW4 are connected in parallel. The input parts 161b and 161d are connected to output parts of the matching circuits 141 and 142, respectively. That is, the switch 55 of the radio frequency module 100 according to the embodiment described above (see FIG. 1) is omitted in the radio frequency module 100 according to the third modification, and the input parts 161b and 161d of the low noise amplifier 161A are connected to the output parts of the matching circuits 141 and 142, respectively, without the switch 55 interposed therebetween in the radio frequency module 100 according to the third modification.

The input parts 161b and 161d of the low noise amplifier 161A are connected to the output parts of the reception filters 61R and 62R with the matching circuits 141 and 142 interposed therebetween, respectively. Thus, reception signals of reception bands of different communication bands are input to the input parts 161b and 161d of the low noise amplifier 161A.

In the low noise amplifier 161A, assuming a reception signal (input signal) is input to the input part 161b, the transistor Tr2 as an amplifier element becomes conductive so that a current corresponding to the reception signal passes through the transistor Tr2 and flows from the first power supply terminal 161a to the ground. The voltage of the first terminal (collector) of the transistor Tr1 at the time of conduction is output, as an amplification signal with respect to the reception signal, from the output part 161c. Furthermore, assuming a reception signal (input signal) is input to the input part 161d, the transistor Tr4 as an amplifier element becomes conductive so that a current corresponding to the reception signal passes through the transistor Tr4 and flows from the first power supply terminal 161a to the ground. The voltage of the first terminal (collector) of the transistor Tr3 at the time of conduction is output, as an amplification signal with respect to the reception signal, from the output part 161c. In the third modification, the transistors Tr2 and Tr4 function as amplifier elements for amplifying signals to be amplified (reception signals mentioned above) input to the input parts 161b and 161d and outputting the amplified signals from the output part 161c.

The switch SW5 is a switch for selectively connecting the output part 161c of the low noise amplifier 161 to one of the multiple (in the example of FIG. 7B, two) signal output terminals 121 and 125. That is, the radio frequency module 100 according to the third modification further includes, as an external connection terminal 110, the signal output terminal 125, in addition to the signal output terminal 121 of the radio frequency module 100 according to the embodiment described above (see FIG. 1). The signal output terminals 121 and 125 are connected to different input parts of the RF signal processing circuit 211. The signal output terminals 121 and 125 correspond to the input parts 161b and 161d of the low noise amplifier 161A on a one-to-one relationship.

The switch Sw5 includes a common terminal and a plurality of (in the example of FIG. 7B, two) selection terminals. The common terminal is connected to the input part 34 of the switch SW5. The input part 34 of the switch SW5 is connected to the output part 161c of the low noise amplifier 161A with the connection wiring unit 33 interposed therebetween. The plurality of selection terminals are connected to the signal output terminals 121 and 125. The common terminal is selectively connected to one of the plurality of selection terminals. Thus, the output part 161c of the low noise amplifier 161A is selectively connected to one of the signal output terminals 121 and 125.

Assuming an amplification signal for a reception signal input to the input part 161b is output from the output part 161c of the low noise amplifier 161A, the switch SW5 connects the output part 161c to the signal output terminal 121 corresponding to the input part 161b. Thus, the reception signal input to the input part 161b is amplified and output from the signal output terminal 121 corresponding to the input part 161b. Furthermore, assuming an amplification signal for a reception signal input to the input part 161d is output from the output part 161c of the low noise amplifier 161A, the switch SW5 connects the output part 161c to the signal output terminal 125 corresponding to the input part 161d. Thus, the reception signal input to the input part 161d is amplified and output from the signal output terminal 125 corresponding to the input part 161d.

As illustrated in FIG. 7A, the semiconductor integrated circuit 1 includes the low noise amplifiers 161A and 162 and the switch SW5. In the example of FIG. 7A, in the semiconductor integrated circuit 1, for example, the low noise amplifiers 161A and 162 and the switch SW5 are arranged in this order from the left to the right on the plane of drawing. Furthermore, the circuit components mentioned above of the low noise amplifier 161A are disposed in a specific arrangement on the first main surface 10a of the circuit substrate 10 of the semiconductor integrated circuit 1. In FIG. 7A, illustration of the arrangement of the circuit components of the low noise amplifier 162 other than the second power supply terminal 162a is omitted. Furthermore, in FIG. 7A, illustration of the arrangement of the circuit components of the switch SW5 other than the input part 34 of the switch SW5 is omitted. Sign 8 in FIG. 7A represents a power supply wiring unit provided at the mounting substrate 2. Sign 16 in FIG. 7A represents the substrate-side wiring part 16 provided at the mounting substrate 2. Signs 14 and 15 in FIG. 7A represent a first circuit-side wiring part and a second circuit-side wiring part that are provided on the first main surface 10a of the circuit substrate 10.

In the third modification, the connection wiring unit 33 is arranged to be routed from the output part 161c of the low noise amplifier 161 to the input part 34 of the switch SW5 and cross the first power supply terminal 161a and the second power supply terminal 162a. A part of the terminal-to-terminal wiring part 13, which connects the first power supply terminal 161a to the second power supply terminal 162a, that crosses the connection wiring unit 33 is arranged, as the substrate-side wiring part 16, to make a detour towards the mounting substrate 2 from the semiconductor integrated circuit 1. That is, the substrate-side wiring part 16 is arranged at the mounting substrate 2 in such a manner that the substrate-side wiring part 16 overlaps with the connection wiring unit 33 in plan view from the thickness direction D1 of the mounting substrate 2. With the substrate-side wiring part 16, the space between the terminal-to-terminal wiring part 13 and the connection wiring unit 33 can be ensured. As a result, a situation where the connection wiring unit 33 is electromagnetically affected by the terminal-to-terminal wiring part 13 can be suppressed.

In the third modification, the low noise amplifier 161A, out of the low noise amplifiers 161A and 162, is a multi-input low noise amplifier including the multiple input parts 161b and 161d. However, both the low noise amplifiers 161A and 162 may be multi-input low noise amplifiers including multiple input parts.

In the third modification, the switch SW5 is connected to the output part of the low noise amplifier 161A, out of the low noise amplifiers 161A and 162, with the connection wiring unit 33 interposed therebetween. However, different switches may be connected to output parts of the low noise amplifiers 161A and 162 with connection wiring units interposed therebetween. In this case, the substrate-side wiring part 16 may be arranged to overlap with connection wiring units for connecting the low noise amplifiers 161A and 162 to the corresponding switches. Here, the substrate-side wiring part 16 may be arranged to overlap with each of the connection wiring units. A single substrate-side wiring part 16 may overlap with each of the connection wiring units or two substrate-side wiring parts 16 may individually overlap with the corresponding connection wiring units. In this case, the terminal-to-terminal wiring part 13 is arranged to make two detours in total in such a manner that, for each connection wiring unit, the terminal-to-terminal wiring part 13 makes a detour towards the mounting substrate 2 from the semiconductor integrated circuit 1.

### (Fourth Modification)

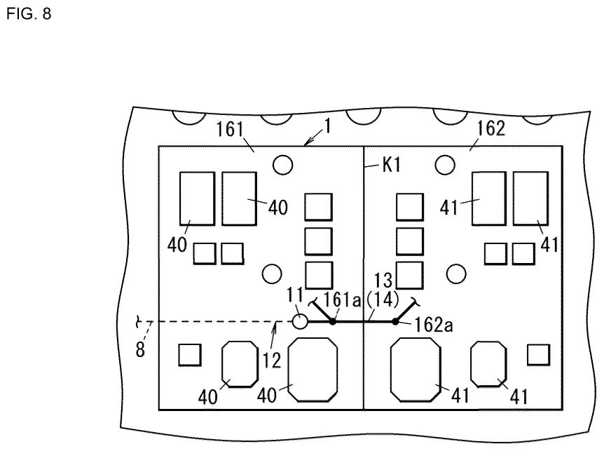

As illustrated in FIG. 8, in a fourth modification, power supply terminals (first power supply terminal 161a and second power supply terminal 162a) of the low noise amplifiers 161 and 162 are arranged to be next to each other. The terminal-to-terminal wiring part 13, which connects the first power supply terminal 161a to the second power supply terminal 162a, does not include the substrate-side wiring part 16 but includes only the first circuit-side wiring part 14 that connects the first power supply terminal 161a to the second power supply terminal 162a. “Two power supply terminals are arranged to be next to each other” represents a state in which no circuit component is disposed between the two power supply terminals on the first main surface 10a of the semiconductor integrated circuit 1. The fourth modification will be described in detail below.

As illustrated in FIG. 8, in the fourth modification, the two low noise amplifiers 161 and 162 are arranged to be next to each other. “Two low noise amplifiers are arranged to be next to each other” represents a state in which no circuit component is arranged between two low noise amplifiers. Furthermore, in the fourth modification, structures of the low noise amplifiers 161 and 162 are linearly symmetrical with respect to a border line K1 in plan view from the thickness direction D1 of the mounting substrate 2. That is, the arrangement of a plurality of circuit components 40 included in the low noise amplifier 161 and the arrangement of a plurality of circuit components 41 included in the low noise amplifier 162 are linearly symmetrical with respect to the border line K1. With this symmetrical structures, the power supply terminals (first power supply terminal 161a and second power supply terminal 162a) of the low noise amplifiers 161 and 162 are arranged near the border line K1 of the low noise amplifiers 161 and 162 and are next to each other.

In the fourth modification, since the first power supply terminal 161a and the second power supply terminal 162a are arranged to be next to each other, no circuit component is disposed between the first power supply terminal 161a and the second power supply terminal 162a. That is, a circuit component that is electromagnetically affected by the terminal-to-terminal wiring part 13 that connects the first power supply terminal 161a to the second power supply terminal 162a is not disposed between the first power supply terminal 161a and the second power supply terminal 162a. Thus, in the fourth modification, the terminal-to-terminal wiring part 13 does not include the substrate-side wiring part 16 but includes the first circuit-side wiring part 14. Sign 8 in FIG. 8 represents a power supply wiring unit provided at the mounting substrate 2. Sign 11 represents the power supply electrode 11 provided at the circuit substrate 10 of the semiconductor integrated circuit 1. Sign 12 represents a power supply wiring unit that connects the power supply electrode 11 to the first power supply terminal 161a and the second power supply terminal 162a.

In the fourth modification, as described above, the terminal-to-terminal wiring part 13 does not overlap with a circuit component that is electromagnetically affected by the terminal-to-terminal wiring part 13. Therefore, a situation where the power supply wiring unit 12 electromagnetically interferes with an amplifier inside the semiconductor integrated circuit 1 can be suppressed.

### (Other Modifications)

In the embodiment described above, an example in which the semiconductor integrated circuit 1 is integrated with the two low noise amplifiers 161 and 162 has been described. However, the semiconductor integrated circuit 1 may be integrated with three or more low noise amplifiers. In this case, the terminal-to-terminal wiring part 13 may connect power supply terminals of the low noise amplifiers in such a manner that the entire terminal-to-terminal wiring part 13 serves as a single wiring part or may connect power supply terminals of the low noise amplifiers in such a manner that the terminal-to-terminal wiring part 13 branches out in the middle of a single wiring part.

Although an example in which the semiconductor integrated circuit 1 includes a low noise amplifier as an amplifier in the embodiment described above, the semiconductor integrated circuit 1 may include a power amplifier as an amplifier or may include a low noise amplifier and a power amplifier.

### (Aspects)

Aspects described below are disclosed by the embodiment and modifications described above.

A radio frequency module (100) according to a first aspect includes a mounting substrate (2), a semiconductor integrated circuit (1), and a power supply wiring unit (12). The semiconductor integrated circuit (1) is arranged at the mounting substrate (2). The semiconductor integrated circuit (1) includes a first amplifier (161), a second amplifier (162), and a power supply electrode (11). The first amplifier (161) includes a first power supply terminal (161a). The second amplifier (162) includes a second power supply terminal (162a). A power supply voltage from the mounting substrate (2) is input to the power supply electrode (11). The power supply wiring unit (12) connects the power supply electrode (11) to the first power supply terminal (161a) and the second power supply terminal (162a). The power supply wiring unit (12) includes a terminal-to-terminal wiring part (13) that connects the first power supply terminal (161a) to the second power supply terminal (162a). The terminal-to-terminal wiring part (13) includes a substrate-side wiring part (16) that is arranged at the mounting substrate (2).

With this arrangement, the terminal-to-terminal wiring part (13) of the power supply wiring unit (12) includes the substrate-side wiring part (16). With the substrate-side wiring part (16), the space between the terminal-to-terminal wiring part (13) and a specific part (17) of an amplifier (the first amplifier (161) or the second amplifier (162) can be ensured. As a result, a situation where the terminal-to-terminal wiring part (13) electromagnetically interferes with the specific part (17) of the amplifier can be suppressed. That is, a situation where the power supply wiring unit (12) electromagnetically interferes with the amplifier (161) inside the semiconductor integrated circuit (1) can be suppressed.

According to a second aspect, in the radio frequency module (100) according to the first aspect, the terminal-to-terminal wiring part (13) further includes a first circuit-side wiring part (14) and a second circuit-side wiring part (15) that are arranged in the semiconductor integrated circuit (1). The first circuit-side wiring part (14) is connected between a first end of the substrate-side wiring part (16) and the first power supply terminal (161a). The second circuit-side wiring part (15) is connected between a second end of the substrate-side wiring part (16) and the second power supply terminal (162a).

With this arrangement, the terminal-to-terminal wiring part (13) includes the first circuit-side wiring part (14) and the second circuit-side wiring part (15) that are arranged in the semiconductor integrated circuit (1). Thus, the first circuit-side wiring part (14) and the second circuit-side wiring part (15) can form a part of the terminal-to-terminal wiring part (13) that is other than the substrate-side wiring part (16).

According to a third aspect, the radio frequency module (100) according to the second aspect includes a first connection member (26) and a second connection member (27). The first connection member (26) is disposed between the mounting substrate (2) and the semiconductor integrated circuit (1) and connects the first circuit-side wiring part (14) to the first end of the substrate-side wiring part (16). The second connection member (27) is disposed between the mounting substrate (2) and the semiconductor integrated circuit (1) and connects the second circuit-side wiring part (15) to the second end of the substrate-side wiring part (16).

With this arrangement, the substrate-side wiring part (16) can be electrically connected to the first circuit-side wiring part (14) and the second circuit-side wiring part (15) by using a simple structure.

According to a fourth aspect, in the radio frequency module (100) according to the third aspect, the first connection member (26) includes a solder bump or bonding wire for connecting the first circuit-side wiring part (14) to the first end of the substrate-side wiring part (16). The second connection member (27) includes a solder bump or bonding wire for connecting the second circuit-side wiring part (15) to the second end of the substrate-side wiring part (16).

With this arrangement, a solder bump or bonding wire can be used to connect the first circuit-side wiring part (14) to the first end of the substrate-side wiring part (16). Furthermore, a solder bump or bonding wire can be used to connect the second circuit-side wiring part (15) to the first end of the substrate-side wiring part (16).

According to a fifth aspect, in the radio frequency module (100) according to any one of the first to fourth aspects, the substrate-side wiring part (16) is arranged inside the mounting substrate (2).

With this arrangement, part of the mounting substrate (2) can be interposed between the substrate-side wiring part (16) and the specific part (17) of the amplifier. With the part of the mounting substrate (2), the situation where the terminal-to-terminal wiring part (13) electromagnetically interferes with the specific part (17) of the amplifier can further be suppressed.

According to a sixth aspect, in the radio frequency module (100) according to any one of the first to fifth aspects, at least one amplifier (161), out of the first amplifier (161) and the second amplifier (162), includes an inductor (L2). The substrate-side wiring part (16) overlaps with the inductor (L2) of the at least one amplifier (161) in plan view from a thickness direction (D1) of the mounting substrate (2).

With this arrangement, the space between the terminal-to-terminal wiring part (13) and the inductor (L2) of the amplifier can be ensured. Thus, a situation where the terminal-to-terminal wiring part (13) electromagnetically interferes with the inductor (L2) of the amplifier can be suppressed.

According to a seventh aspect, in the radio frequency module (100) according to the sixth aspect, the at least one amplifier (161) further includes a power supply terminal (161a) and an amplifier element (Tr2). The power supply terminal (161a) is connected to the power supply wiring unit (12). The amplifier element (Tr2) is connected between the power supply terminal (161a) and a ground and amplifies an input signal to be amplified. The inductor (L2) is connected between the amplifier element (Tr2) and the ground.

With this arrangement, a situation where, as the inductor of the amplifier, the inductor (L2) in the amplifier connected between the amplifier element (Tr2) and the ground is electromagnetically interfered with by the terminal-to-terminal wiring part (13) can be suppressed.

According to an eighth aspect, in the radio frequency module (100) according to any one of the first to seventh aspects, at least one of the first amplifier (161A) and the second amplifier (162) is an amplifier to which a plurality of signals of different communication bands are input.

With this arrangement, the present disclosure can be applied to the semiconductor integrated circuit (1) that includes a multi-input amplifier (161A) as the amplifier.

According to a ninth aspect, the radio frequency module (100) according to any one of the first to eighth aspects further includes a plurality of signal output terminals (121, 125) and a switch (SW5) that selectively connects an output part (161c) of one amplifier (161A), out of the first amplifier (161A) and the second amplifier (162), to one of the plurality of signal output terminals (121, 125). The substrate-side wiring part (16) overlaps with a wiring unit (33) that connects the one amplifier (161A) to the switch (SW5) in plan view from a thickness direction (D1) of the mounting substrate (2).

With this arrangement, with the substrate-side wiring part (16), the space between the wiring unit (33), which connects the one amplifier (161A) to the switch (SW5), and the terminal-to-terminal wiring part (13) can be ensured. As a result, a situation where the terminal-to-terminal wiring part (13) electromagnetically interferes with the wiring unit (33) can be suppressed.

According to a tenth aspect, the radio frequency module (100) according to the third aspect includes a plurality of connection members. The plurality of connection members include the first connection member (26) and the second connection member (27). The semiconductor integrated circuit (1) includes a plurality of amplifiers including the first amplifier (161; 161A) and the second amplifier (162). The plurality of amplifiers each include a power supply terminal. The terminal-to-terminal wiring part (13) connects the power supply terminals of the plurality of amplifiers. The terminal-to-terminal wiring part (13) includes a plurality of substrate-side wiring parts including the substrate-side wiring part (16) and a plurality of circuit-side wiring parts including the first circuit-side wiring part (14) and the second circuit-side wiring part (15). Each of the plurality of connection members is disposed between the mounting substrate (2) and the semiconductor integrated circuit (1). Each of the plurality of connection members connects one of the plurality of circuit-side wiring parts to one of the plurality of substrate-side wiring parts. The number of the plurality of connection members is greater than the number of the plurality of amplifiers.

With this arrangement, in the case where the terminal-to-terminal wiring part (13) includes the substrate-side wiring part (16), the number of the connection conductors is highly likely to be greater than the number of the amplifiers. Thus, the determination as to whether or not the substrate-side wiring part (16) according to the present disclosure is used can be easily made by determining whether or not the number of the connection conductors is greater than the number of the amplifiers.

According to an eleventh aspect, in the radio frequency module (100) according to any one of the first to tenth aspects, the first amplifier and the second amplifier include a low noise amplifier (161; 161A, 162).

With this arrangement, the present disclosure can be applied to a case where the first amplifier and the second amplifier include a low pass noise amplifier (161; 161A, 162).

According to a twelfth aspect, in the radio frequency module (100) according to any one of the first to tenth aspects, the first amplifier and the second amplifier include a power amplifier (151, 152).

With this arrangement, the present disclosure can be applied to a case where the first amplifier and the second amplifier include a power amplifier (151, 152).

According to a thirteenth aspect, the radio frequency module (100) according to any one of the first to twelfth aspects further includes a matching circuit (141, 142) that includes an inductor and is connected to one amplifier (161), out of the first amplifier (161) and the second amplifier (162). The mounting substrate (2) has a first main surface (2a) and a second main surface (2b) that are opposite to each other. The inductor of the matching circuit (141, 142) is disposed on the first main surface (2a) of the mounting substrate (2). The semiconductor integrated circuit (1) is disposed on the second main surface (2b) of the mounting substrate (2). The inductor of the matching circuit (141, 142) overlaps with the semiconductor integrated circuit (1) in a thickness direction (D1) of the mounting substrate (2).

With this arrangement, the semiconductor integrated circuit (1) and the matching circuit (141, 142) are disposed on individual sides of the mounting substrate (2), and the matching circuit (141, 142) overlaps with the semiconductor integrated circuit (1) in the thickness direction (D1) of the mounting substrate (2). Thus, the length of a wiring unit that connects the semiconductor integrated circuit (1) to the matching circuit (141, 142) can be reduced. By shortening the wiring unit, entry of noise into the wiring part can be suppressed.

According to a fourteenth aspect, in the radio frequency module (100) according to any one of the first to thirteenth aspects, the mounting substrate (2) includes a ground layer (30). The ground layer (30) is disposed between the substrate-side wiring part (16) and the semiconductor integrated circuit (1) in a thickness direction (D1) of the mounting substrate (2).

With this arrangement, the ground layer (30) can be disposed between the substrate-side wiring part (16) and the semiconductor integrated circuit (1). With the ground layer (30), the situation where the terminal-to-terminal wiring part (13) electromagnetically interferes with the specific part (17) of the amplifier can further be suppressed.

According to a fifteenth aspect, a communication apparatus (200) includes the radio frequency module (100) according to any one of the first to fourteenth aspects and a signal processing circuit (210). The signal processing circuit (210) is connected to the radio frequency module (100) and performs signal processing for a radio frequency signal.

With this arrangement, the communication apparatus (200) that includes the radio frequency module (100) achieving an operation affect described above can be provided.

### REFERENCE SIGNS LIST

1, 3 semiconductor integrated circuit
2 mounting substrate
2a first main surface
2b second main surface
4 first resin layer
5 second resin layer
6 shield layer
7 power supply electrode
8, 12 power supply wiring unit
10 circuit substrate
10a first main surface
10b second main surface
11 power supply electrode
13 terminal-to-terminal wiring part
14 first circuit-side wiring part
15 second circuit-side wiring part
16 substrate-side wiring part
17 specific part
18, 19, 21, 22 electrode
20 first connection conductor
23 second connection conductor
26 first connection member
27 second connection member
29 connection conductor
30 ground layer
33 connection wiring unit (wiring unit)
34 input part
36 wiring part
40, 41 circuit component
51 to 56 switch
60 matching circuit
61 to 63 duplexer
61R to 64T reception filter
61T to 63T transmission filter
71 to 74 matching circuit
80 controller
100 radio frequency module
110 external connection terminal
111 to 114 signal input terminal
121, 122, 125 signal output terminal
123 power supply input terminal
124 input terminal
130 antenna terminal
131 output matching circuit
132 output matching circuit
141 to 144 matching circuit
151, 152 power amplifier
161, 161A low noise amplifier (first amplifier)
162 low noise amplifier (second amplifier)
161a first power supply terminal
161b input part
161c output part
161d input part
162a second power supply terminal
200 communication apparatus
210 signal processing circuit
211 RF signal processing circuit
212 baseband signal processing circuit
220 antenna
C1 to C3 capacitor
D1 thickness direction
K1 border line
L1, L2 inductor
R1 resistor
S0 to S3 signal path
SW1, SW3 to SW5 switch
Tr1, Tr3, Tr4 transistor
Tr2 transistor (amplifier element)
V1 power supply

1. A radio frequency module comprising:
a mounting substrate;
a semiconductor integrated circuit that is arranged at the mounting substrate; and
a power supply wiring unit,
wherein the semiconductor integrated circuit includes
a first amplifier that includes a first power supply terminal,
a second amplifier that includes a second power supply terminal, and
a power supply electrode to which a power supply voltage from the mounting substrate is input,
wherein the power supply wiring unit connects the power supply electrode to the first power supply terminal and the second power supply terminal,
wherein the power supply wiring unit includes a terminal-to-terminal wiring part that connects the first power supply terminal to the second power supply terminal, and
wherein the terminal-to-terminal wiring part includes a substrate-side wiring part that is arranged at the mounting substrate.

2. The radio frequency module according to claim 1,
wherein the terminal-to-terminal wiring part further includes a first circuit-side wiring part and a second circuit-side wiring part that are arranged in the semiconductor integrated circuit,
wherein the first circuit-side wiring part is connected between a first end of the substrate-side wiring part and the first power supply terminal, and
wherein the second circuit-side wiring part is connected between a second end of the substrate-side wiring part and the second power supply terminal.

3. The radio frequency module according to claim 2, further comprising:
a first connection member that is disposed between the mounting substrate and the semiconductor integrated circuit and connects the first circuit-side wiring part to the first end of the substrate-side wiring part; and
a second connection member that is disposed between the mounting substrate and the semiconductor integrated circuit and connects the second circuit-side wiring part to the second end of the substrate-side wiring part.

4. The radio frequency module according to claim 3,
wherein the first connection member includes a solder bump or bonding wire for connecting the first circuit-side wiring part to the first end of the substrate-side wiring part, and
wherein the second connection member includes a solder bump or bonding wire for connecting the second circuit-side wiring part to the second end of the substrate-side wiring part.

5. The radio frequency module according to claim 4,
wherein the substrate-side wiring part is arranged inside the mounting substrate.

6. The radio frequency module according to claim 5,
wherein at least one amplifier, out of the first amplifier and the second amplifier, includes an inductor, and
wherein the substrate-side wiring part overlaps with the inductor of the at least one amplifier in plan view from a thickness direction of the mounting substrate.

7. The radio frequency module according to claim 6,
wherein the at least one amplifier further includes
a power supply terminal that is connected to the power supply wiring unit, and
an amplifier element that is connected between the power supply terminal and a ground and amplifies an input signal to be amplified, and
wherein the inductor is connected between the amplifier element and the ground.

8. The radio frequency module according to claim 7,
wherein at least one of the first amplifier and the second amplifier is an amplifier to which a plurality of signals of different communication bands are input.

9. The radio frequency module according to claim 8, further comprising:
a plurality of signal output terminals; and
a switch that selectively connects an output part of one amplifier, out of the first amplifier and the second amplifier, to one of the plurality of signal output terminals,
wherein the substrate-side wiring part overlaps with a wiring unit that connects the one amplifier to the switch in plan view from a thickness direction of the mounting substrate.

10. The radio frequency module according to claim 3, comprising:
a plurality of connection members including the first connection member and the second connection member,
wherein the semiconductor integrated circuit includes
a plurality of amplifiers including the first amplifier and the second amplifier,
wherein the plurality of amplifiers each include a power supply terminal,
wherein the terminal-to-terminal wiring part
connects the power supply terminals of the plurality of amplifiers, and
includes
a plurality of substrate-side wiring parts including the substrate-side wiring part, and
a plurality of circuit-side wiring parts including the first circuit-side wiring part and the second circuit-side wiring part,
wherein each of the plurality of connection members is disposed between the mounting substrate and the semiconductor integrated circuit and connects one of the plurality of circuit-side wiring parts to one of the plurality of substrate-side wiring parts, and
wherein the number of the plurality of connection members is greater than the number of the plurality of amplifiers.

11. The radio frequency module according to claim 10,
wherein the first amplifier and the second amplifier include a low noise amplifier.

12. The radio frequency module according to claim 10,
wherein the first amplifier and the second amplifier include a power amplifier.

13. The radio frequency module according to claim 12, further comprising:
a matching circuit that includes an inductor and is connected to one amplifier, out of the first amplifier and the second amplifier,
wherein the mounting substrate has a first main surface and a second main surface that are opposite to each other,
wherein the inductor of the matching circuit is disposed on the first main surface of the mounting substrate,
wherein the semiconductor integrated circuit is disposed on the second main surface of the mounting substrate, and
wherein the inductor of the matching circuit overlaps with the semiconductor integrated circuit in a thickness direction of the mounting substrate.

14. The radio frequency module according to claim 13,
wherein the mounting substrate includes a ground layer, and
wherein the ground layer is disposed between the substrate-side wiring part and the semiconductor integrated circuit in a thickness direction of the mounting substrate.

15. A communication apparatus comprising:
the radio frequency module according to claim 14; and
a signal processing circuit that is connected to the radio frequency module and performs signal processing for a radio frequency signal.

16. The radio frequency module according to claim 1,
wherein the substrate-side wiring part is arranged inside the mounting substrate.

17. The radio frequency module according to claim 1,
wherein at least one amplifier, out of the first amplifier and the second amplifier, includes an inductor, and
wherein the substrate-side wiring part overlaps with the inductor of the at least one amplifier in plan view from a thickness direction of the mounting substrate.

18. The radio frequency module according to claim 1,
wherein at least one of the first amplifier and the second amplifier is an amplifier to which a plurality of signals of different communication bands are input.

19. The radio frequency module according to claim 1, further comprising:
a plurality of signal output terminals; and
a switch that selectively connects an output part of one amplifier, out of the first amplifier and the second amplifier, to one of the plurality of signal output terminals,
wherein the substrate-side wiring part overlaps with a wiring unit that connects the one amplifier to the switch in plan view from a thickness direction of the mounting substrate.

20. The radio frequency module according to claim 1,
wherein the first amplifier and the second amplifier include a low noise amplifier.
